(19) United States
(12) Patent Application Publication
(10) Pub. No.: US 2017/0255044 A1
(43) Pub. Date: Sep. 7, 2017

(54) TFT SUBSTRATES AND THE MANUFACTURING METHODS THEREOF

(71) Applicant: Shenzhen China Star Optoelectronics Technology Co., Ltd., Shenzhen, Guangdong (CN)

(72) Inventor: Shimin GE, Shenzhen (CN)

(73) Assignee: Shenzhen China Star Optoelectronics Technology Co., Ltd., Shenzhen, Guangdong (CN)

(21) Appl. No.: 14/786,110

(22) PCT Filed: Sep. 30, 2015
(86) PCT No.: PCT/CN2015/091284

§ 371 Date: Oct. 21, 2015

(30) Foreign Application Priority Data
Sep. 28, 2015 (CN) 201510627108.8

(51) Int. Cl. G02F 1/1368; G02F 1/1362; G02F 1/1343

(52) U.S. Cl. CPC G02F 1/1368; G02F 1/13439; G02F 1/136227; H01L 27/1225

(57) ABSTRACT

A TFT array substrate and the manufacturing method are disclosed, one masking process is adopted to etch the first metal oxide semiconductor layer to be the first semiconductor pattern and the second semiconductor pattern. Afterward, a doping process is applied to the first semiconductor pattern and the second semiconductor pattern. Two ends of the first semiconductor pattern are processed to be a first conductor pattern and a second conductor pattern spaced apart from each other. In addition, the second semiconductor pattern is processed to be a common electrode. The remaining first semiconductor pattern is above the bottom gate electrode. In this way, the number of masking processes adopted during the manufacturing process of the array substrate is decreased, such that the manufacturing efficiency is enhanced and the manufacturing cost is reduced.

### BACKGROUND OF THE INVENTION

### 1. Field of the Invention

The present disclosure relates to liquid crystal display technology, and more particularly to a TFT array substrate and the manufacturing method thereof.

### 2. Discussion of the Related Art

Active Matrix LCD display technology utilizes the bi-directional polarization attributes of liquid crystals. The alignment of the liquid crystal molecules are controlled by the applied electrical field to implement the switch functions of optical paths of the backlight source. The LCD display modes may include TN, VA and IPS modes in accordance with the directions of the applied electrical field. Regarding VA mode, the vertical electrical field is applied to the liquid crystal molecules. Regarding IPS mode, the horizontal electrical field is applied to the liquid crystal molecules. However, IPS mode may further include IPS mode and FPS mode in accordance with the applied horizontal electrical field. With respect to the FFS mode, each of the pixel cells includes two electrode arranged respectively in an up layer and a down layer, i.e., a pixel electrode and a common electrode. In addition, the opening area of the common electrode in the down layer covers the whole surface. FFS mode has been widely adopted due to the attributes including high transmission rate, wide viewing angle and low color shift.

With respect to the active array display devices, usually, single-gate TFT is adopted. Compared to the Dual gate TFT, the single-gate TFT is characterized by the attributes such as high mobility, larger on-state current, smaller subthreshold swing, good Vth stability, and good uniformity. In addition, the stability of the grid bias is also better. However, more number of masking processes has to be performed in the manufacturing method of the traditional FFS mode of the dual-gate TFT array substrate, which increases the complexity of the manufacturing method and also the manufacturing cost.

### SUMMARY

The object of the invention is to a TFT array substrate and the manufacturing method thereof for reducing the number of masks so as to enhance the manufacturing efficiency and the cost.

In one aspect, a manufacturing method of TFT array substrates includes: providing a substrate; forming a first metallic layer on the substrate, and etching the first metallic layer by a first masking process to be a bottom gate electrode; forming a first metal oxide semiconductor layer on the substrate, and adopting a second masking process to etch the first metal oxide semiconductor layer to be a first semiconductor pattern and a second semiconductor pattern, applying a doping process to process the first semiconductor pattern to be a first conductor pattern and second conductor pattern and to process the second semiconductor pattern to be a third conductor pattern, the first conductor pattern and the second conductor pattern are spaced apart from each other, wherein remaining first semiconductor pattern is above the bottom gate electrode, and the third conductor pattern operates as a common electrode; wherein photoresist patterns are formed on the metal oxide semiconductor layer, the photoresist patterns includes a first photoresist pattern corresponding to the first semiconductor pattern and a second photoresist pattern corresponding to the second metal oxide semiconductor layer, a thickness of a middle area of the first photoresist patterns is larger than the thickness of two ends of the first photoresist patterns and is larger than the thickness of the second photoresist patterns; the first photoresist patterns and the second photoresist patterns are adopted as masks to etch the metal oxide semiconductor layer to be a first semiconductor pattern and a second semiconductor pattern; adopting a plasma treatment toward the first semiconductor pattern and the second semiconductor pattern with the mask of the first photoresist patterns and the second photoresist patterns, processing the two ends of the first semiconductor pattern to be the first conductor pattern and the second conductor pattern, and processing the second semiconductor pattern to be the third conductor pattern; forming an etch blocking layer on the substrate, and adopting a sixth masking process to etch the etch blocking layer to form through holes on the etch blocking layer respectively above the first conductor pattern and the second conductor pattern;

forming a second metallic layer on the substrate, and adopting a third masking process to etch the second metallic layer to be a source electrode and a drain electrode, wherein the drain electrode covers the first semiconductor pattern, and the source electrode covers the second semiconductor pattern; forming a passivation layer on the substrate, and adopting a fourth masking process to etch the passivation layer to form a through hole; forming a second metal oxide semiconductor layer on the substrate, and adopting a fifth masking process to etch the second metal oxide semiconductor layer to form a top gate electrode and the pixel electrode, wherein the top gate electrode is above the remaining first semiconductor pattern, and at least a portion of the pixel electrode is overlapped with the common electrode, and one of the pixel electrodes electrically connects to the source electrode or the drain electrode via the through hole.

Wherein the metal oxide semiconductor layer is IGZO metal oxide semiconductor layer.

Wherein the second masking process adopts the photoresist pattern, which is one of the half-tone mask (HTM), gray-tone mask (GTM) and single slit mask (SSM).

Wherein the etch blocking layer is made by SiOx.

In another aspect, a manufacturing method of TFT array substrates includes: providing a substrate; forming a first metallic layer on the substrate, and etching the first metallic layer by a first masking process to be a bottom gate electrode; forming a first metal oxide semiconductor layer on the substrate, and adopting a second masking process to etch the first metal oxide semiconductor layer to be a first semiconductor pattern and a second semiconductor pattern, applying a doping process to process the first semiconductor pattern to be a first conductor pattern and second conductor pattern and to process the second semiconductor pattern to be a third conductor pattern, the first conductor pattern and the second conductor pattern are spaced apart from each other, wherein remaining first semiconductor pattern is above the bottom gate electrode, and the third conductor pattern operates as a common electrode; forming a second metallic layer on the substrate, and adopting a third masking process to etch the second metallic layer to be a source electrode and a drain electrode, wherein the drain electrode covers the first semiconductor pattern, and the source electrode covers the second semiconductor pattern; forming a passivation layer on the substrate, and adopting a fourth masking process to etch the passivation layer to form a through hole; and forming a second metal oxide semiconductor layer on the substrate, and adopting a fifth masking process to etch the second metal oxide semiconductor layer to form a top gate electrode and the pixel electrode, wherein the top gate electrode is above the remaining first semiconductor pattern, and at least a portion of the pixel electrode is overlapped with the common electrode, and one of the pixel electrodes electrically connects to the source electrode or the drain electrode via the through hole.

Wherein the metal oxide semiconductor layer is IGZO metal oxide semiconductor layer.

Wherein the step of forming a first metal oxide semiconductor layer on the substrate, adopting a second masking process to etch the first metal oxide semiconductor layer to be a first semiconductor pattern and a second semiconductor pattern, and applying a doping process to process the first semiconductor pattern further includes: wherein photoresist patterns are formed on the metal oxide semiconductor layer, the photoresist patterns includes a first photoresist pattern corresponding to the first semiconductor pattern and a second photoresist pattern corresponding to the second metal oxide semiconductor layer, a thickness of a middle area of the first photoresist patterns is larger than the thickness of two ends of the first photoresist patterns and is larger than the thickness of the second photoresist patterns; the first photoresist patterns and the second photoresist patterns are adopted as masks to etch the metal oxide semiconductor layer to be a first semiconductor pattern and a second semiconductor pattern; and adopting a plasma treatment toward the first semiconductor pattern and the second semiconductor pattern with the mask of the first photoresist patterns and the second photoresist patterns, processing the two ends of the first semiconductor pattern to be the first conductor pattern and the second conductor pattern, and processing the second semiconductor pattern to be the third conductor pattern.

Wherein the second masking process adopts the photoresist pattern, which is one of the half-tone mask (HTM), gray-tone mask (GTM) and single slit mask (SSM).

Wherein the method further includes a step between the step of forming a first metal oxide semiconductor layer on the substrate, adopting a second masking process to etch the first metal oxide semiconductor layer to be a first semiconductor pattern and a second semiconductor pattern, and applying a doping process to process the first semiconductor pattern and the step of forming a second metallic layer on the substrate, and adopting a third masking process to etch the second metallic layer to be a source electrode and a drain electrode, and the step includes: forming an etch blocking layer on the substrate, and adopting a sixth masking process to etch the etch blocking layer to form through holes on the etch blocking layer respectively above the first conductor pattern and the second conductor pattern.

Wherein the etch blocking layer is made by SiOx.

In another aspect, a TFT array substrate includes: a substrate; a bottom gate formed on the substrate; a semiconductor pattern formed on the substrate, a first conductor pattern and a second conductor pattern at two ends of the semiconductor pattern, a common electrode, the first conductor pattern and the second semiconductor pattern are spaced apart from each other, and wherein the semiconductor pattern, the first conductor pattern, the second conductor pattern, and the common electrode are formed by the same metal oxide semiconductor layer.

Wherein the metal oxide semiconductor layer is IGZO metal oxide semiconductor layer.

Wherein the array substrate further includes a drain electrode above the first conductor pattern and a source electrode above the second conductor pattern.

Wherein the array substrate further includes an etch blocking layer being provided with through holes respectively corresponding to the first conductor pattern and the second conductor pattern, and the drain electrode and the source electrode electrically connect to the semiconductor pattern via the through holes.

In view of the above, one masking process is adopted to etch the first metal oxide semiconductor layer to be the first semiconductor pattern and the second semiconductor pattern. Afterward, a doping process is applied to the first semiconductor pattern and the second semiconductor pattern. Two ends of the first semiconductor pattern are processed to be a first conductor pattern and a second conductor pattern spaced apart from each other. In addition, the second semiconductor pattern is processed to be a common electrode. The remaining first semiconductor pattern is above the bottom gate electrode. In this way, the number of masking processes adopted during the manufacturing process of the array substrate is decreased, such that the manufacturing efficiency is enhanced and the manufacturing cost is reduced.

### BRIEF DESCRIPTION OF THE DRAWINGS

FIG. 1 is a flowchart of the manufacturing method of the TFT array substrate in accordance with a first embodiment.

FIGS. 2A-2G are the schematic views of the bottom electrode, the common electrode, the first conductive pattern and the second conductive pattern manufactured by the method of FIG. 1.

FIG. 3 is a schematic view of the source electrode and the drain electrode formed by the third mask process of the TFT array substrate of FIG. 1.

FIG. 4 is a schematic view of the through hole formed by the fourth mask of the TFT array substrate of FIG. 1.

FIG. 5 is a schematic view of the TFT array substrate formed by the manufacturing method in the first embodiment of FIG. 1.

FIG. 6 is a flowchart of the manufacturing method of the TFT array substrate in accordance with a second embodiment.

FIG. 7 is a schematic view of the TFT array substrate formed by the manufacturing method in the second embodiment of FIG. 6.

### DETAILED DESCRIPTION OF THE EMBODIMENTS

Embodiments of the invention will now be described more fully hereinafter with reference to the accompanying drawings, in which embodiments of the invention are shown.

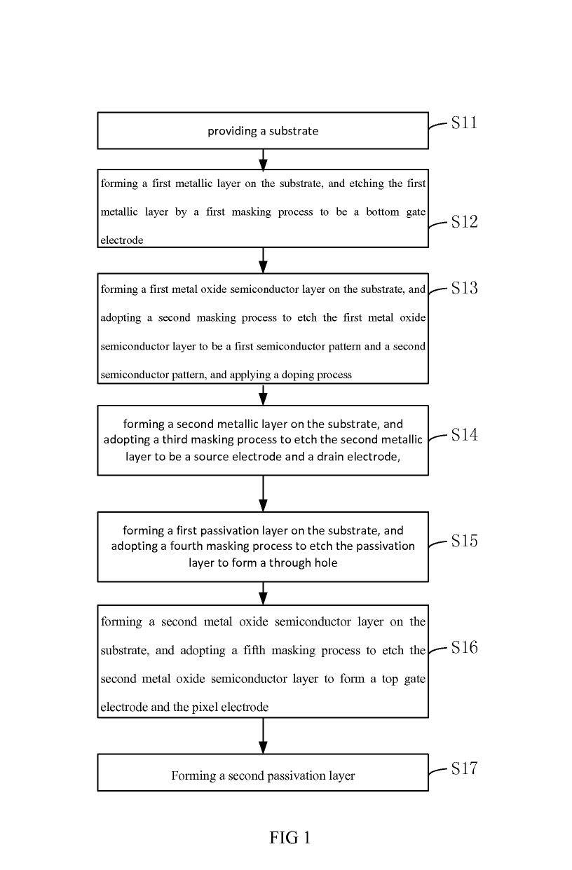

FIG. 1 is a flowchart of the manufacturing method of the TFT array substrate in accordance with a first embodiment. The method includes:

In block S11, a substrate is provided.

In block S12, a first metallic layer is formed on the substrate, and the first metallic layer is etched by a first masking process to be a bottom gate electrode.

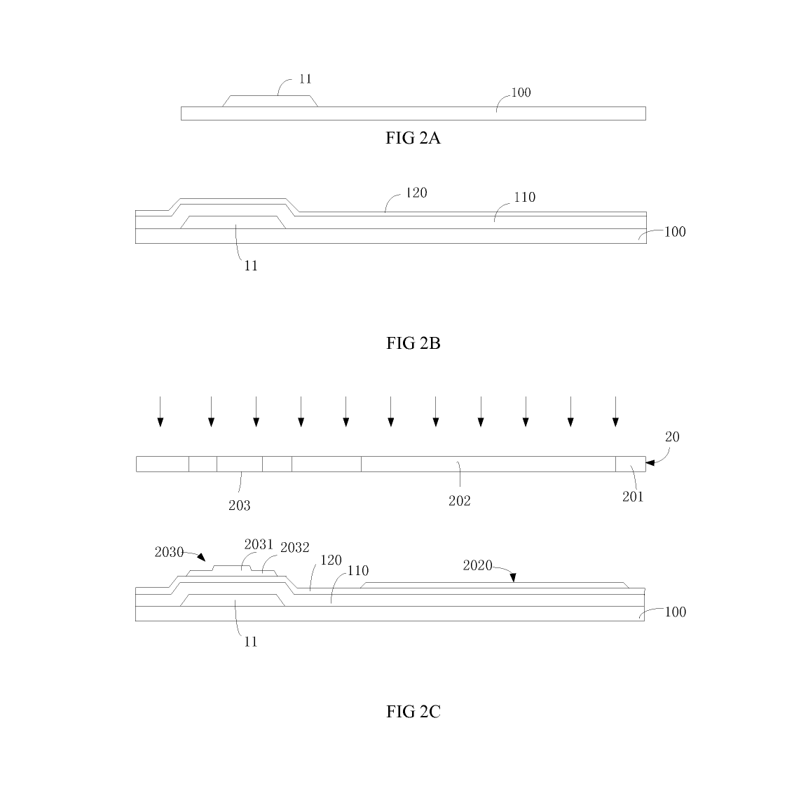

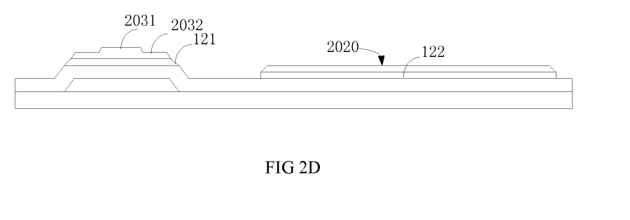

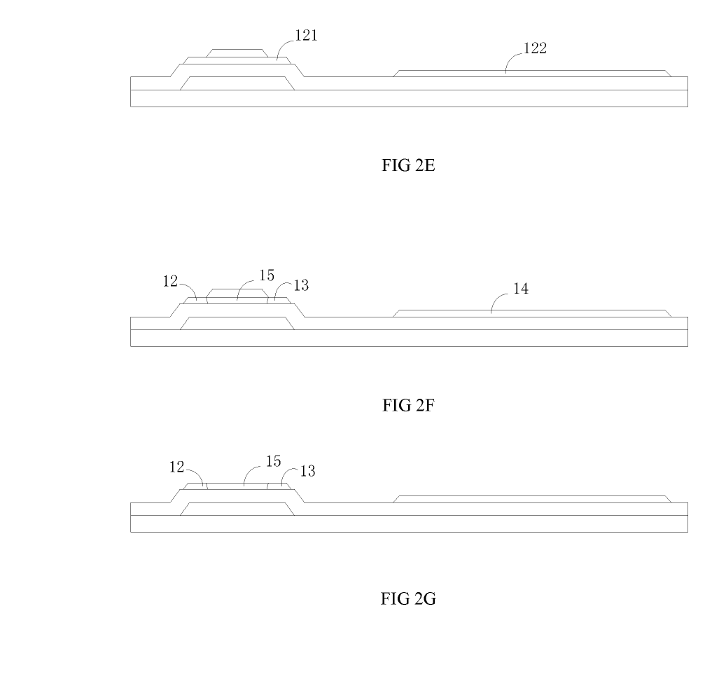

FIG. 2A is a schematic view of the bottom gate electrode formed by the manufacturing method in the first embodiment, as shown in FIG. 1. The substrate 100 is a base substrate. The substrate 100 may be a glass substrate, a plastic substrate or the substrate of other suitable materials. In the embodiment, the substrate 100 is a glass substrate, which is translucent.

The first metallic layer (not shown) is deposited on the substrate 100 by PVD. The first metallic layer may be made by materials including, but not limited to, chromium, aluminum, titanium, or other metallic materials. The first metallic layer in FIG. 2A has been exposed and etched to obtain the substrate bottom gate electrode 11.

In block S13, a first metal oxide semiconductor layer is formed on the substrate, and a second masking process is adopted to etch the first metal oxide semiconductor layer. After being etched, the first semiconductor pattern and a second semiconductor pattern are formed and then are doped.

As shown in FIG. 2B, a gate insulation layer 110 covers the substrate 100. Further, a first metal oxide semiconductor layer 120 is formed on the gate insulation layer 110 via PVD. The gate insulation layer 110 covers the substrate 11 and extends into the substrate 100. The gate insulation layer 110 may be formed by PVD. The gate insulation layer 110 may be made by materials including, but not limited to, SiNx, SiOx, or SiOxNy. The first metal oxide semiconductor layer 120 may be made by Indium Gallium Zinc Oxide (IGZO), which is amorphous metal oxide including indium, gallium and zinc. The IGZO is the material of trench layers of newly developed thin film transistor. The carrier mobility ratio of the IGZO is about 20 to 30 times than the amorphous silicon, which can greatly enhance the charge-discharge rate of the TFT toward the pixel electrode. Also, the response speed of the pixel and the refresh rate are enhanced. At the same time, the row scanning rate of the pixels may has quickly response so as to realize high resolution in the TFT-LCD field. In addition, as the number of the transistors is decreased and the optical transmission rate of each of the pixels is enhanced, the IGZO display devices may have higher energy efficiency level and higher efficiency. In addition, IGZO may be manufactured by manufacturing lines of amorphous silicon with slight change. Thus, the competitiveness of the IGZO cost is higher than that of the low temperature poly silicon (LTPS).

Referring to FIG. 2C, a photoresist layer (not shown) covers the first metal oxide semiconductor layer 120. A second mask 20 is adopted to expose and develop the photoresist layer. The second mask 20 may be any one of half-tone mask (HTM), gray-tone mask (GTM) or single slit mask (SSM). The second mask 20 includes a light transmission portion 201, a translucent portion 202, and an opaque portion 203. The second mask 20 is adopted to expose the substrate 100 of the first metal oxide semiconductor layer 120. A portion of the photoresist layer corresponding to the light transmission portion 201 of the second mask 20 has been fully exposed. The portion of the photoresist corresponding to the translucent portion 202 of the second mask 20 has been semi-exposed. The portion of the photoresist corresponding to the opaque portion 203 of the second mask 20 is not exposed. Thus, the second mask 20 is adopted to perform the exposition, semi-exposition, non-exposition, and development to obtain a first photoresist pattern 2030 and a second photoresist pattern 2020. The first photoresist pattern 2030 includes a first photoresist portion 2031 and a second photoresist portion 2032. The second photoresist pattern 2020 includes the second photoresist portion 2032. A thickness of the first photoresist portion 2031 is larger than that of the second photoresist portion 2032. The first photoresist pattern 2030 includes the first photoresist portion 2031 in the middle. Two ends of the first photoresist portion 2031 includes the photoresist patterns of the second photoresist portion 2032. The first photoresist portion 2031 corresponds to the opaque portion 203 of the second mask 20, and the second photoresist portion 2032 corresponds to the translucent portion 202 of the second mask 20.

As shown in FIG. 2D, the wet etching process is applied to the area that has not been covered by the photoresist portion. In the embodiment, the area relates to the area corresponding to the first metal oxide semiconductor layer 120 that has not been covered by the first photoresist pattern 2030 and the second photoresist pattern 2020. Thus, when the first metal oxide semiconductor layer 120 has been exposed, developed, and etched by the second mask 20, the second semiconductor pattern 122 below the second photoresist pattern 2020 and the first semiconductor pattern 121 below the first photoresist pattern 2030 are formed.

As shown in FIG. 2E, the oxygen is adopted to perform an ashing process to the first photoresist portion 2031 and the second photoresist portion 2032 so as to remove the thinner portion of the second photoresist portion 2032, and thus the area corresponding to the first metal oxide semiconductor layer 120 covered by the second photoresist portion 2032 is exposed. A portion of the first photoresist portion 2031 is maintained. In the embodiment, the second semiconductor pattern 122 below the second photoresist pattern 2020 is exposed, and two ends of the first semiconductor pattern 121 below the first photoresist pattern 2030 are also exposed.

Referring to FIG. 2F, a plasma treatment with helium or argon is adopted such that the area of the first metal oxide semiconductor layer 120 that has not been covered by the photoresist is processed to be a corresponding conductor. The area of the first metal oxide semiconductor layer 120 that has been covered by the photoresist is still a conductor. In the embodiment, the IGZO semiconductor layer is processed to be a corresponding IGZO conductor via Plasma treatment. By the Plasma treatment, the second semiconductor pattern 122 is processed to be a corresponding third conductor pattern 14, the two ends of the first semiconductor pattern 121 is processed to be a first conductor pattern 12 and a second conductor pattern 13, and the first conductor pattern 12 and the second conductor pattern 13 are spaced apart from each other. The first metal oxide semiconductor layer 120 covered by the photoresist portion has not been processed by the Plasma treatment.

Referring to FIG. 2G, the remaining first photoresist portion 2031 is striped such that the first metal oxide semiconductor layer 120 covered by the remaining first photoresist portion 2031 is maintained to be a semiconductor pattern 15. Thus, two ends of the semiconductor pattern 15 are respectively the first conductor pattern 12 and the second conductor pattern 13, the semiconductor pattern 15 is arranged above the bottom gate electrode 11, and the third conductor pattern 14 operates as the common electrode 14 of the array substrate.

In block S14, a second metallic layer is formed on the substrate, and a third masking process is adopted to etch the second metallic layer to be a source electrode and a drain electrode.

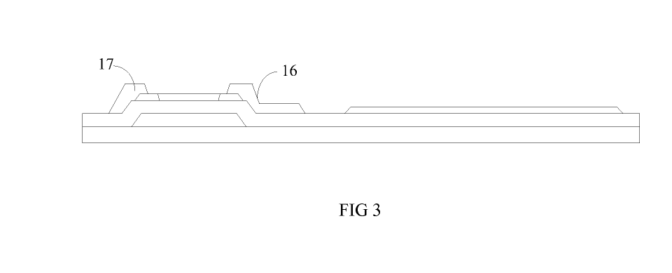

As shown in FIG. 3, a second metallic layer (not shown) is formed on the substrate 100, and a photoresist layer (not shown) is formed on the second metallic layer. A third mask (not shown) is adopted to expose, develop, and etch the photoresist layer on the second metallic layer. As such, the drain electrode 17 on the first conductor pattern 12 and the source electrode 16 on the second conductor pattern 13 are formed. The third masking process for forming the source electrode 16 and the drain electrode 17 are conventional solution, and thus the details are omitted hereinafter.

In block S15, a passivation layer is formed on the substrate, and a fourth masking process is adopted to etch the passivation layer to form a through hole.

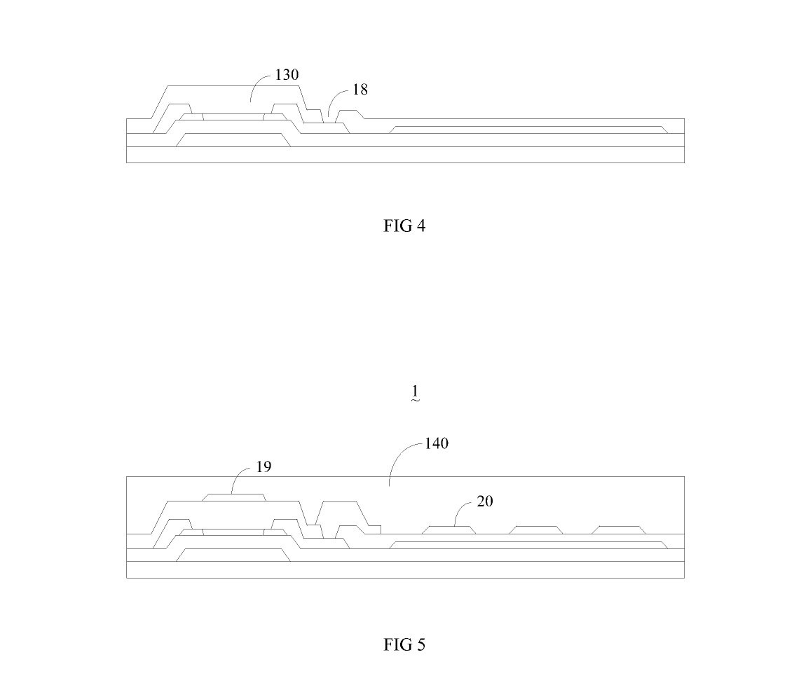

As shown in FIG. 4, a passivation layer 130 is formed on the substrate 100. The passivation layer 130 covers the source electrode 16, the drain electrode 17, the third conductor pattern 14 and then extends into the gate insulation layer 110. The fourth masking (not shown) is adopted to expose, develop, and etch the passivation layer 130 so as to form a through hole 18 in an area of the passivation layer 130 above the source electrode 16 or the drain electrode 17. The method of forming the through hole 18 relates to a conventional solution, and thus the details are omitted hereinafter.

In block S16, a second metal oxide semiconductor layer is formed on the substrate, and a fifth masking process is adopted to etch the second metal oxide semiconductor layer 120 to form a top gate electrode and the pixel electrode.

In block S17, a second passivation layer is formed on the substrate.

FIG. 5 is a schematic view of the TFT array substrate formed by the manufacturing method in the first embodiment of FIG. 1. FIG. 5 illustrates the steps including S16 and S17. A second metal oxide semiconductor layer (not shown) is formed on the passivation layer 130 of the substrate 100. The second metal oxide semiconductor layer may be made by Indium tin oxide (ITO), which is metal oxide having good conductance and transparency.

A fifth mask (not shown) is adopted to expose, develop, and etch the second metal oxide semiconductor layer so as to form a top gate electrode 19 and a plurality of pixel electrodes 20. The top gate electrode 19 is opposite to the bottom gate electrode 11. At least a portion of the pixel electrode 20 is overlapped with the common electrode 14, and one of the pixel electrodes 20 electrically connects to the source electrode 16 or the drain electrode 17 via the through hole 18. In FIG. 5, the pixel electrode 20 electrically connects to the source electrode 16 via the through hole 18, and the other pixel electrodes 20 are spaced apart from each other over the common electrode 14. A second passivation layer 140 covers the pixel electrodes 20, the top gate electrode 19 and extends into the passivation layer 130.

The process of forming the pixel electrode 20 and the top gate electrode 19 relates to conventional solution, and thus the details are omitted hereinafter. In the embodiment, the metal oxide TFT array 1 is the array substrate having back channel etch (BCE) structure.

In view of the above, one masking process is adopted to etch the first metal oxide semiconductor layer to be the first semiconductor pattern and the second semiconductor pattern. Afterward, a doping process is applied to the first semiconductor pattern and the second semiconductor pattern. Two ends of the first semiconductor pattern are processed to be a first conductor pattern and a second conductor pattern spaced apart from each other. In addition, the second semiconductor pattern is processed to be a common electrode. The remaining first semiconductor pattern is above the bottom gate electrode. In this way, the number of masking processes adopted during the manufacturing process of the array substrate is decreased, such that the manufacturing efficiency is enhanced and the manufacturing cost is reduced.

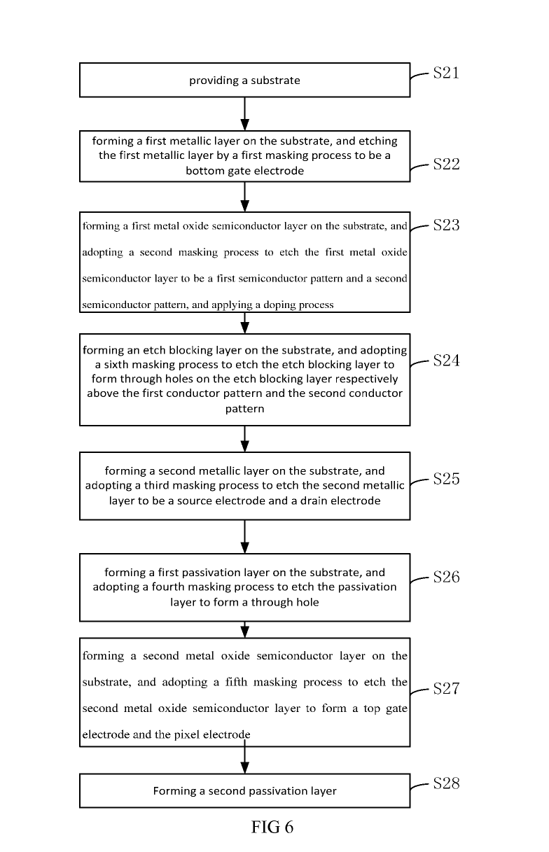

FIG. 6 is a flowchart of the manufacturing method of the TFT array substrate in accordance with a second embodiment. The method includes the following steps.

In block S21, a substrate is provided.

In block S22, a first metallic layer is formed on the substrate, and the first metallic layer is etched by a first masking process to be a bottom gate electrode.

In block S23, a first metal oxide semiconductor layer is formed on the substrate, and a second masking process is adopted to etch the first metal oxide semiconductor layer. After being etched, the first semiconductor pattern and a second semiconductor pattern are formed and then are doped.

In block S24, an etch blocking layer is formed on the substrate, and a sixth masking process is adopted to etch the etch blocking layer to form through holes on the etch blocking layer respectively above the first conductor pattern and the second conductor pattern.

In block S25, a second metallic layer is formed on the substrate, and a third masking process is adopted to etch the second metallic layer to be a source electrode and a drain electrode.

In block S26, a passivation layer is formed on the substrate, and a fourth masking process is adopted to etch the passivation layer to form a through hole.

In block S27, a second metal oxide semiconductor layer is formed on the substrate, and a fifth masking process is adopted to etch the second metal oxide semiconductor layer 120 to form a top gate electrode and the pixel electrode.

In block S28, a second passivation layer is formed on the substrate.

Referring to FIGS. 1-5, the second mask is adopted to form the first semiconductor pattern 121 and the second semiconductor pattern 122, and a doping process is adopted to form the first conductor pattern 12 and the second conductor pattern 13, the third conductor pattern 14, and the semiconductor pattern 15. In this embodiment, an etch blocking layer 150 is formed on the substrate 100.

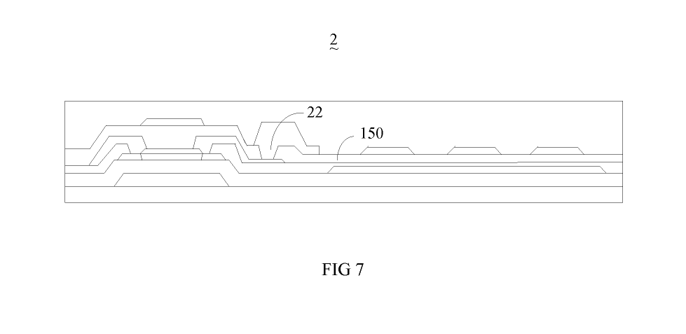

FIG. 7 is a schematic view of the TFT array substrate formed by the manufacturing method in the second embodiment of FIG. 6. The etch blocking layer 150 covers the semiconductor pattern 15, the common electrode 14, and extends into the gate insulation layer 110. The etch blocking layer 150 may be made by, but not limited to, SiOx.

A sixth mask (not shown) is adopted to expose, develop, and etch the etch blocking layer 150. The areas of the etch blocking layer corresponding to the first conductor pattern 12 and the second conductor pattern 13 are exposed and etched to form the through holes of the etch blocking layer 22. The through holes of the etch blocking layer 22 are configured for electrically connecting to the first conductor pattern 12 and the second conductor pattern 13, respectively. The etch blocking layer 150 is configured for protecting the semiconductor pattern 15, the first conductor pattern 12, and the second conductor pattern 13 during the manufacturing process of the source electrode 16 and the drain electrode 17. The blocks of S25-S28 in the embodiment are similar to the blocks of S14-S17, and thus are omitted hereinafter.

In the embodiment, the array substrate 2 may be of the Etch stopper layer (ESL) array substrate. The difference between the ESL array substrate and the BCE array substrate resides in that the ESL array substrate 2 may further includes the etch blocking layer 150. The areas of the etch blocking layer 150 corresponding to the first conductor pattern 12 and the second conductor pattern 13 are provided with the through holes of the etch blocking layer 22. As such, the source electrode 16 and the drain electrode 17 above the first conductor pattern 12 and the second conductor pattern 13 may electrically connect to the first conductor pattern 12 and the second conductor pattern 13 via the through holes of the etch blocking layer 22.

In view of the above, the manufacturing process of the array substrate is similar to that in the first embodiment. In this way, the number of masking processes adopted during the manufacturing process of the array substrate is decreased, such that the manufacturing efficiency is enhanced and the manufacturing cost is reduced. In addition, by configuring the etch blocking layer 150, the semiconductor pattern 15, the first conductor pattern 12, and the second conductor pattern 13 are protected during the etching process is applied to the drain electrode and the source electrode.

In view of the above, one masking process is adopted to etch the first metal oxide semiconductor layer to be the first semiconductor pattern and the second semiconductor pattern. Afterward, a doping process is applied to the first semiconductor pattern and the second semiconductor pattern. Two ends of the first semiconductor pattern are processed to be a first conductor pattern and a second conductor pattern spaced apart from each other. In addition, the second semiconductor pattern is processed to be a common electrode. The remaining first semiconductor pattern is above the bottom gate electrode. In this way, the number of masking processes adopted during the manufacturing process of the array substrate is decreased, such that the manufacturing efficiency is enhanced and the manufacturing cost is reduced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of TFT array substrates, comprising:
providing a substrate;
forming a first metallic layer on the substrate, and etching the first metallic layer by a first masking process to be a bottom gate electrode;
forming a first metal oxide semiconductor layer on the substrate, and adopting a second masking process to etch the first metal oxide semiconductor layer to be a first semiconductor pattern and a second semiconductor pattern, applying a doping process to process the first semiconductor pattern to be a first conductor pattern and second conductor pattern and to process the second semiconductor pattern to be a third conductor pattern, the first conductor pattern and the second conductor pattern are spaced apart from each other, wherein remaining first semiconductor pattern is above the bottom gate electrode, and the third conductor pattern operates as a common electrode;
wherein photoresist patterns are formed on the metal oxide semiconductor layer, the photoresist patterns comprises a first photoresist pattern corresponding to the first semiconductor pattern and a second photoresist pattern corresponding to the second metal oxide semiconductor layer, a thickness of a middle area of the first photoresist patterns is larger than the thickness of two ends of the first photoresist patterns and is larger than the thickness of the second photoresist patterns;
the first photoresist patterns and the second photoresist patterns are adopted as masks to etch the metal oxide semiconductor layer to be a first semiconductor pattern and a second semiconductor pattern;
adopting a plasma treatment toward the first semiconductor pattern and the second semiconductor pattern with the mask of the first photoresist patterns and the second photoresist patterns, processing the two ends of the first semiconductor pattern to be the first conductor pattern and the second conductor pattern, and processing the second semiconductor pattern to be the third conductor pattern;
forming an etch blocking layer on the substrate, and adopting a sixth masking process to etch the etch blocking layer to form through holes on the etch blocking layer respectively above the first conductor pattern and the second conductor pattern;
forming a second metallic layer on the substrate, and adopting a third masking process to etch the second metallic layer to be a source electrode and a drain electrode, wherein the drain electrode covers the first semiconductor pattern, and the source electrode covers the second semiconductor pattern;
forming a passivation layer on the substrate, and adopting a fourth masking process to etch the passivation layer to form a through hole;
forming a second metal oxide semiconductor layer on the substrate, and adopting a fifth masking process to etch the second metal oxide semiconductor layer to form a top gate electrode and the pixel electrode, wherein the top gate electrode is above the remaining first semiconductor pattern, and at least a portion of the pixel electrode is overlapped with the common electrode, and one of the pixel electrodes electrically connects to the source electrode or the drain electrode via the through hole.

2. The manufacturing method as claimed in claim 1, wherein the metal oxide semiconductor layer is IGZO metal oxide semiconductor layer.

3. The manufacturing method as claimed in claim 1, wherein the second masking process adopts the photoresist pattern, which is one of the half-tone mask (HTM), gray-tone mask (GTM) and single slit mask (SSM).

4. The manufacturing method as claimed in claim 1, wherein the etch blocking layer is made by SiOx.

5. A manufacturing method of TFT array substrates, comprising:
providing a substrate;
forming a first metallic layer on the substrate, and etching the first metallic layer by a first masking process to be a bottom gate electrode;
forming a first metal oxide semiconductor layer on the substrate, and adopting a second masking process to etch the first metal oxide semiconductor layer to be a first semiconductor pattern and a second semiconductor pattern, applying a doping process to process the first semiconductor pattern to be a first conductor pattern and second conductor pattern and to process the second semiconductor pattern to be a third conductor pattern, the first conductor pattern and the second conductor pattern are spaced apart from each other, wherein remaining first semiconductor pattern is above the bottom gate electrode, and the third conductor pattern operates as a common electrode;
forming a second metallic layer on the substrate, and adopting a third masking process to etch the second metallic layer to be a source electrode and a drain electrode, wherein the drain electrode covers the first semiconductor pattern, and the source electrode covers the second semiconductor pattern;
forming a passivation layer on the substrate, and adopting a fourth masking process to etch the passivation layer to form a through hole; and
forming a second metal oxide semiconductor layer on the substrate, and adopting a fifth masking process to etch the second metal oxide semiconductor layer to form a top gate electrode and the pixel electrode, wherein the top gate electrode is above the remaining first semiconductor pattern, and at least a portion of the pixel electrode is overlapped with the common electrode, and one of the pixel electrodes electrically connects to the source electrode or the drain electrode via the through hole.

6. The manufacturing method as claimed in claim 5, wherein the metal oxide semiconductor layer is IGZO metal oxide semiconductor layer.

7. The manufacturing method as claimed in claim 5, wherein the step of forming a first metal oxide semiconductor layer on the substrate, adopting a second masking process to etch the first metal oxide semiconductor layer to be a first semiconductor pattern and a second semiconductor pattern, and applying a doping process to process the first semiconductor pattern further comprises:
wherein photoresist patterns are formed on the metal oxide semiconductor layer, the photoresist patterns comprises a first photoresist pattern corresponding to the first semiconductor pattern and a second photoresist pattern corresponding to the second metal oxide semiconductor layer, a thickness of a middle area of the first photoresist patterns is larger than the thickness of two ends of the first photoresist patterns and is larger than the thickness of the second photoresist patterns;
the first photoresist patterns and the second photoresist patterns are adopted as masks to etch the metal oxide semiconductor layer to be a first semiconductor pattern and a second semiconductor pattern; and
adopting a plasma treatment toward the first semiconductor pattern and the second semiconductor pattern with the mask of the first photoresist patterns and the second photoresist patterns, processing the two ends of the first semiconductor pattern to be the first conductor pattern and the second conductor pattern, and processing the second semiconductor pattern to be the third conductor pattern.

8. The manufacturing method as claimed in claim 7, wherein the second masking process adopts the photoresist pattern, which is one of the half-tone mask (HTM), gray-tone mask (GTM) and single slit mask (SSM).

9. The manufacturing method as claimed in claim 5, wherein the method further comprises a step between the step of forming a first metal oxide semiconductor layer on the substrate, adopting a second masking process to etch the first metal oxide semiconductor layer to be a first semiconductor pattern and a second semiconductor pattern, and applying a doping process to process the first semiconductor pattern and the step of forming a second metallic layer on the substrate, and adopting a third masking process to etch the second metallic layer to be a source electrode and a drain electrode, and the step comprises:
forming an etch blocking layer on the substrate, and adopting a sixth masking process to etch the etch blocking layer to form through holes on the etch blocking layer respectively above the first conductor pattern and the second conductor pattern.

10. The manufacturing method as claimed in claim 9, wherein the etch blocking layer is made by SiOx.

11. A TFT array substrate, comprising:
a substrate;
a bottom gate formed on the substrate;
a semiconductor pattern formed on the substrate, a first conductor pattern and a second conductor pattern at two ends of the semiconductor pattern, a common electrode, the first conductor pattern and the second semiconductor pattern are spaced apart from each other, and wherein the semiconductor pattern, the first conductor pattern, the second conductor pattern, and the common electrode are formed by the same metal oxide semiconductor layer.

12. The array substrate as claimed in claim 11, wherein the metal oxide semiconductor layer is IGZO metal oxide semiconductor layer.

13. The array substrate as claimed in claim 11, wherein the array substrate further comprises a drain electrode above the first conductor pattern and a source electrode above the second conductor pattern.

14. The array substrate as claimed in claim 13, wherein the array substrate further comprises an etch blocking layer being provided with through holes respectively corresponding to the first conductor pattern and the second conductor pattern, and the drain electrode and the source electrode electrically connect to the semiconductor pattern via the through holes.
